(19) United States
(12) Patent Application Publication
(10) Pub. No.: US 2026/0068760 A1
(43) Pub. Date: Mar. 5, 2026

(54) SEMICONDUCTOR PACKAGE AND METHOD OF FABRICATING THE SAME

(71) Applicant: Samsung Electronics Co., Ltd., Suwon-si (KR)

(72) Inventor: Seungryong OH, Suwon-si (KR)

(73) Assignee: Samsung Electronics Co., Ltd., Suwon-si (KR)

(21) Appl. No.: 19/178,096

(22) Filed: Apr. 14, 2025

(30) Foreign Application Priority Data
Aug. 28, 2024 (KR) 10-2024-0116002

(51) Int. Cl. H01L 25/16; H01L 23/00; H01L 23/29; H01L 23/31; H01L 23/48

(52) U.S. Cl. CPC H01L 25/16

(57) ABSTRACT

Provided is a semiconductor package with improvement in warpage thereof and a method of fabricating the semiconductor package. The semiconductor package includes a first semiconductor chip, a redistribution substrate on the first semiconductor chip, a second semiconductor chip on the redistribution substrate, a first encapsulant encapsulating the second semiconductor chip, on the redistribution substrate, a metal post arranged on a top surface of the first semiconductor chip, and a second encapsulant covering side surfaces of the metal post, on the bottom surface of the first semiconductor chip.

### CROSS-REFERENCE TO RELATED APPLICATION

This application is based on and claims priority under 35 U.S.C. § 119 to Korean Patent Application No. 10-2024-0116002, filed on Aug. 28, 2024, in the Korean Intellectual Property Office, the disclosure of which is incorporated by reference herein in its entirety.

### BACKGROUND

The inventive concepts relate to a semiconductor package, and more particularly, to a semiconductor package in which semiconductor chips are vertically stacked, and a method of fabricating the same.

In accordance with rapid development in the electronics field and requirements of users, sizes and weights of electronic devices have been more and more reduced. In accordance with reduction in sizes and weights of electronic devices, sizes and weights of semiconductor packages used in the electronic devices also have been reduced, and in addition to high performance and large capacities, higher reliability is sought for semiconductor packages. Recently, according to improvement in the intensity of semiconductor devices and the performance of peripheral devices, a structure in which chips are vertically stacked has been employed in semiconductor packages. According to whether interposers are included or are omitted, semiconductor packages having a stack structure are sorted into a three-dimensional (3D) package structure, a 2.5-D package structure, and/or the like.

### SUMMARY

The inventive concepts provide a semiconductor package of which warpage is improved, and a method of fabricating the semiconductor package.

Technical goals to be achieved by the inventive concepts are not limited to the aforementioned technical goal, and other technical goals may be clearly understood to those skilled in the art based on the following descriptions.

According to an aspect of the inventive concepts, there is provided a semiconductor package including a first semiconductor chip, a redistribution substrate on a top surface of the first semiconductor chip, a second semiconductor chip on a top surface of the redistribution substrate such that the redistribution substrate connects the second semiconductor chip to the first semiconductor chip, a first encapsulant on the redistribution substrate and encapsulating the second semiconductor chip, a metal post on a bottom surface of the first semiconductor chip, and a second encapsulant on the bottom surface of the first semiconductor chip and covering side surfaces of the metal post.

According to another inventive concepts, there is provided a semiconductor package including a first semiconductor chip, a second semiconductor chip over the first semiconductor chip, a first encapsulant over the first semiconductor chip and encapsulating the second semiconductor chip, a metal post on a bottom surface of the first semiconductor chip, a second encapsulant on the bottom surface of the first semiconductor chip and covering side surfaces of the metal post, and a first connection terminal on a bottom surface of the metal post, wherein a top surface of the first semiconductor chip includes an active surface and a bottom surface of the second semiconductor chip comprises an active surface.

According to another aspect of the inventive concepts, there is provided a semiconductor package including a first semiconductor chip, a second semiconductor chip over the first semiconductor chip, a first encapsulant over the first semiconductor chip and encapsulating the second semiconductor chip, a metal post on a bottom surface of the first semiconductor chip, and a second encapsulant on the bottom surface of the first semiconductor chip and covering side surfaces of the metal post.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to at least one embodiment;

FIGS. 2A and 2B are cross-sectional to describe warpage of semiconductors in a comparative example and at least one embodiment;

FIGS. 3A and 3B are cross-sectional views illustrating warpage of semiconductor packages in a comparative example and at least one embodiment at a wafer-level;

FIGS. 4A and 4B are cross-sectional views of a semiconductor package according to some embodiments;

FIGS. 5A and 5B are cross-sectional views of a semiconductor package according to some embodiments;

FIGS. 6A to 6D are cross-sectional views of a semiconductor package according to some embodiment;

FIGS. 7A and 7H are cross-sectional views schematically illustrating a method of fabricating a semiconductor package, according to at least one embodiment;

FIGS. 8A to 8D are cross-sectional views schematically illustrating a method of fabricating a semiconductor package, according to at least one embodiment; and

FIGS. 9A to 9D are cross-sectional views schematically illustrating a method of fabricating a semiconductor package, according to at least one embodiment.

### DETAILED DESCRIPTION OF THE EMBODIMENTS

Hereinafter, embodiments of the inventive concepts will be described in detail with reference to the accompanying drawings. Same reference numerals will be used for same components in the drawings, and descriptions thereof will not be repeatedly given. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Additionally, spatially relative terms, such as “above”, “lower” “below”, and/or similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

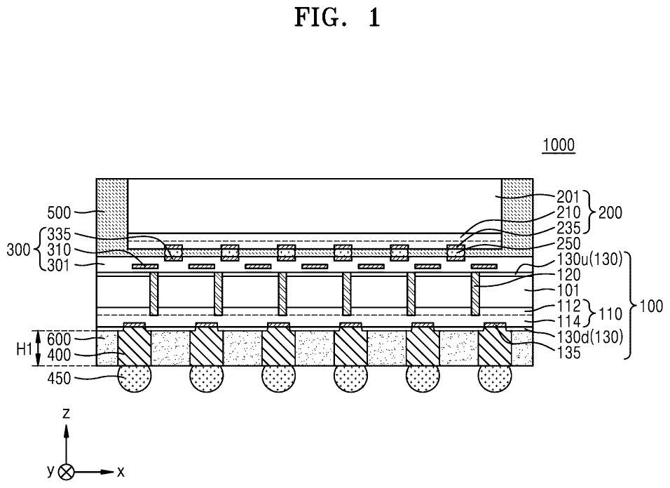

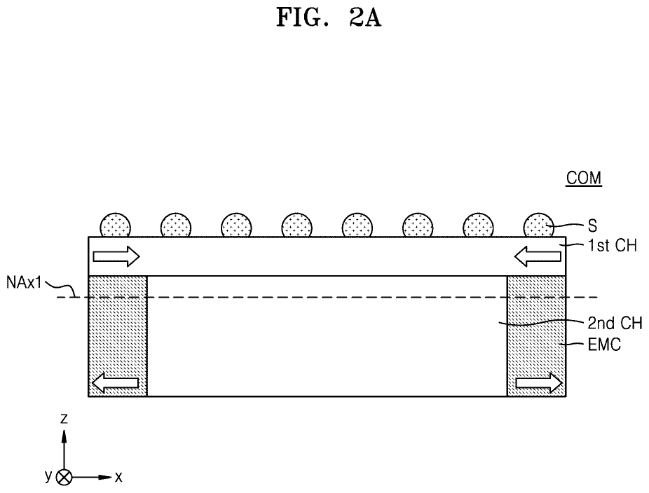

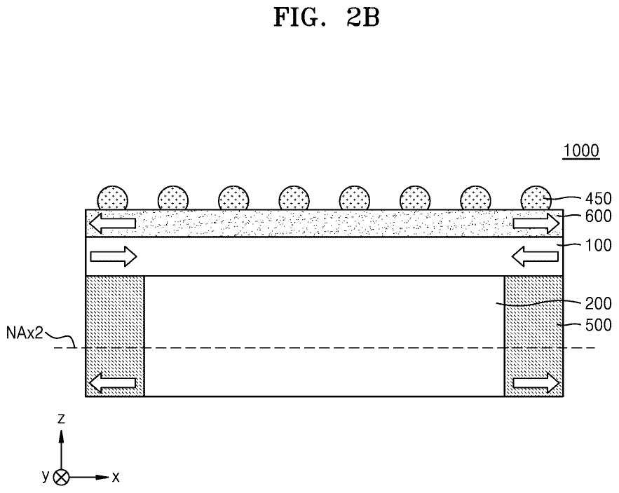

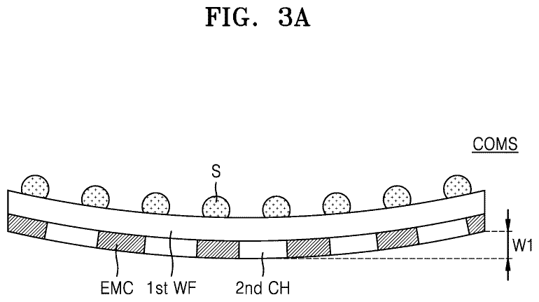

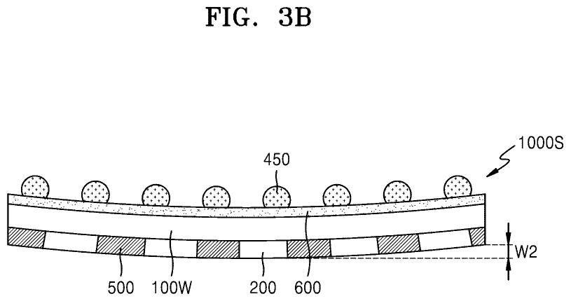

FIG. 1 is a cross-sectional view of a semiconductor package 1000 according to at least one embodiment, FIGS. 2A and 2B are cross-sectional views to describe warpage of semiconductor packages in a comparative example and the at least one embodiment, and FIGS. 3A and 3B are cross-sectional views illustrating wafer-level warpage in a comparative example and the at least one embodiment.

Referring to FIGS. 1 to 3B, the semiconductor package 1000 in the present embodiment includes a first semiconductor chip 100, a second semiconductor chip 200, a redistribution substrate 300, a metal post 400, a first encapsulant 500, and a second encapsulant 600.

In the semiconductor package 1000 of the present embodiment, the first semiconductor chip 100 may include a logic chip. However, the first semiconductor chip 100 is not limited to the logic chip. For example, in some embodiments, the first semiconductor chip 100 may also include a memory chip. When the first semiconductor chip 100 includes the logic chip, the first semiconductor chip 100 may include a plurality of logic devices therein. Here, a logic device may be a device configured to perform various types of signal processing and may include, e.g., an AND, an OR, a NOT, a flip-flop, and/or the like.

For example, the first semiconductor chip 100 may include a modem chip configured to support communication of the second semiconductor chip 200. However, the type of the first semiconductor chip 100 is not limited to a modem chip. For example, the first semiconductor chip 100 may include various types of integrated devices configured to perform separate calculations and/or to support operations of the second semiconductor chip 200. In some embodiments, the first semiconductor chip 100 may include a multi-channel input/output (I/O) interface configured to exchange memory signals with memory devices. In addition, the first semiconductor chip 100 may include Static random-access Memory (SRAM) for temporarily storing data.

As illustrated in FIG. 1, the first semiconductor chip 100 may include a substrate 101, an active layer 110, a through electrode 120, and a protective layer 130. The substrate 101 may include an elemental semiconductor (e.g., a Group IV semiconductor (such as silicon (Si), e.g., monocrystalline Si, polycrystalline Si (poly Si), or amorphous Si, and/or germanium (Ge))), a compound semiconductor (e.g., a Group IV-IV compound semiconductor (such as silicon germanium (SiGe) and/or silicon carbide (SiC)), or a Group III-V semiconductor (such as gallium arsenide (GaAs), indium arsenide (InAs), indium phosphide (InP), etc.)) and/or the like.

The substrate 101 may be based on a Si bulk substrate. In addition, the substrate 101 may also be based on a silicon-on-insulator (SOI) substrate and/or a germanium-on-insulator (GeOI) substrate; however, the substrate 101 is not limited to the bulk substrate, the SOI substrate, or the GeOI substrate, and may be, e.g., based on an epitaxial wafer, a polished wafer, an annealed wafer, and/or the like.

The active layer 110 may be arranged under the substrate 101. The active layer 110 may include an integrated circuit layer 112 and a multi-distribution layer 114. The integrated circuit layer 112 may be formed by using an impurity region at a lower portion of the substrate 101. For example, the integrated circuit layer 112 may include a plurality of transistors each including one or more impurity regions (e.g., a source/drain region) and a gate electrode. However, components included in the integrated circuit layer 112 are not limited to transistors. The multi-distribution layer 114 may be arranged under the integrated circuit layer 112. The multi-distribution layer 114 may include a plurality of distribution lines arranged in multi layers, and distribution lines in different layers may be connected through vias. A chip pad 135 electrically connected to the distribution lines in the multi-distribution layer may be arranged on a bottom surface of the active layer 110. As illustrated in FIG. 1, the metal post 400 may be arranged on the chip pad 135 and may be configured to form an electrical path between the chip pad 135 and an external device (not illustrated).

The through electrode 120 may penetrate through the substrate 101 and extend in a vertical direction (a z direction). A bottom surface of the through electrode 120 may be connected to the distribution lines of the multi-distribution layer 114 of the active layer 110, and a top surface of the through electrode 120 may be connected to a redistribution line 310 of the redistribution substrate 300. For example, an upper pad (not shown) may be arranged on the top surface of the through electrode 120, and the redistribution line 310 may be electrically connected to the through electrode 120 through the upper pad. Accordingly, the first semiconductor chip 100 may be connected to the redistribution substrate 300 through the through electrode 120. In addition, the first semiconductor chip 100 may be electrically connected to the second semiconductor chip 200 through the through electrode 120, the redistribution substrate 300, and a second connection terminal 250.

The through electrode 120 has a structure penetrating silicon included in the substrate 101, and thus may be referred to as a through silicon via (TSV). For reference, the through electrode 120 may be sorted into a via-first structure formed before the integrated circuit layer 112 of the active layer 110 is formed, a via-middle structure formed after the integrated circuit layer 112 and before the multi-distribution layer 114 of the active layer 110, and a via-last structure formed after the multi-distribution layer 114. In FIG. 1, the through electrode 120 may correspond to, e.g., the via middle structure. However, the embodiment is not limited thereto, and in the semiconductor package 1000 of the present embodiment, the through electrode 120 may also have the via-first structure or the via-last structure.

The protective layer 130 may include a lower protective layer 130d on a bottom surface of the active layer 110 and an upper protective layer 130u on a top surface of the substrate 101. As illustrated in FIG. 1, the metal post 400 may penetrate the lower protective layer 130d and be connected to the chip pad 135. In addition, the through electrode 120 and/or the upper pad on the through electrode 120 may be arranged in a structure penetrating the upper protective layer 130u. The protective layer 130 may include an insulating material (e.g., a silicon oxide film, a silicon nitride film, a silicon oxynitride film, and/or the like). In addition, the protective layer 130 may include a multi-film structure, e.g., a silicon oxide film/a silicon nitride film/a silicon oxynitride film. However, materials or multi-film structures of the protective layer 130 are not limited thereto.

In the first semiconductor chip 100, a bottom surface may also be referred to as a front-side (that is, the active surface), and a top surface may also be referred to as a back-side (that is, an inactive surface). In other words, the bottom surface of the active layer 110 may correspond to the front-side of the first semiconductor chip 100 and the top surface of the substrate 101 may correspond to the back-side of the first semiconductor chip 100. The chip pad 135 may be formed on the front-side, that is, the active surface, and the metal post 400 may be arranged on the chip pad 135.

The redistribution substrate 300 may be arranged on the first semiconductor chip 100. The redistribution substrate 300 may include a body insulating layer 301, the redistribution line 310, and a substrate pad 335. The body insulating layer 301 may include an insulating material, e.g., a Photo Imageable Dielectric (PID) resin or a Photo Imageable Polyimide (PIP) resin, and may further include an inorganic filler. However, materials of the body insulating layer 301 are not limited thereto. For example, the body insulating layer 301 may include polyimide isoindro quirazorindione (PIQ), polyimide (PI), polybenzoxazole (PBO), and/or the like.

The body insulating layer 301 may include a multi-layer structure according to the multi-layer structure of the redistribution line 310. However, in FIG. 1, the body insulating layer 301 is illustrated in a single-layer structure, for convenience. When the body insulating layer 301 has the multi-layer structure, all layers of the body insulating layer 301 may include a same material, or at least one of the layers may include another material.

The redistribution line 310 may be arranged in a multi-layer structure in the body insulating layer 301. The redistribution lines 310 arranged in different layers may be connected to each other through one or more vertical vias (not illustrated). The redistribution line 310 and the vertical via may include a conductive material (e.g., a zero-bandgap material and/or the like), for example, copper (Cu). However, materials of the redistribution line 310 and the vertical via are not limited to Cu.

The second connection terminal 250 may be arranged on a top surface of the body insulating layer 301. The second connection terminal 250 may be arranged on the substrate pad 335 arranged on the top surface of the body insulating layer 301. In some embodiments, the substrate pad 335 may be included as a portion of the redistribution line 310. A bottom surface of the body insulating layer 301 may be in contact with the through electrode 120 of the first semiconductor chip 100. The through electrode 120 may be connected to the redistribution line 310 through an upper pad of the first semiconductor chip 100 and/or a lower substrate pad of the redistribution substrate 300. The second connection terminal 250 may include a conductive material and/or alloy, such as a solder, and may electrically connect the first semiconductor chip 100 and the second semiconductor chip 200.

The second semiconductor chip 200 may be mounted on the redistribution substrate 300 through a second connection terminal 250. In the semiconductor package 1000 of the present embodiment, the second semiconductor chip 200 may include a logic chip. Accordingly, the second semiconductor chip 200 may include a plurality of logic devices therein. In the semiconductor package 1000 of the present embodiment, the second semiconductor chip 200 may include, for example, an Application Processor (AP) chip. In addition, the second semiconductor chip 200 may include a control chip, a processor chip, a Central Processing Unit (CPU) chip, a Graphics Processing Unit (GPU) chip, a Neutral Processing Unit (NPU) chip, and/or the like. Together with the first semiconductor chip 100, or independently, the second semiconductor chip 200 may include a System on Chip (SoC).

The second semiconductor chip 200 may include a substrate 201, an active layer 210, and a chip pad 235. The active layer 210 may include an integrated circuit layer and a multi-distribution layer. The integrated circuit layer may include a plurality of integrated devices. The multi-distribution layer may be arranged under the integrated circuit layer and may include a plurality of distribution lines in a multi-layer structure. The second connection terminal 250 may be arranged on the chip pad 235. In the second semiconductor chip 200, a bottom surface may also be referred to as a front-side (that is an active surface), and a top surface may also be referred to as a back-side (that is an inactive surface). In other words, a bottom surface of the active layer 210 may correspond to the front-side of the second semiconductor chip 200, and a top surface of the substrate 201 may correspond to the back-side of the second semiconductor chip 200.

The second semiconductor chip 200 is not limited to a logic chip. For example, the second semiconductor chip 200 may include a memory chip. In addition, the second semiconductor chip 200 may also have a package structure, instead of a single-chip structure. When the second semiconductor chip 200 has the package structure, the second semiconductor chip 200 may include a plurality of memory chips. The memory chips may include a volatile memory device (e.g., Dynamic random-access memory (DRAM) or SRAM), or a nonvolatile memory device such as flash memory. In the semiconductor package 1000 of the present embodiment, when the second semiconductor chip 200 includes a memory chip, the memory chip may include, for example, a DRAM chip. However, a type of the second semiconductor chip 200 is not limited to a DRAM chip.

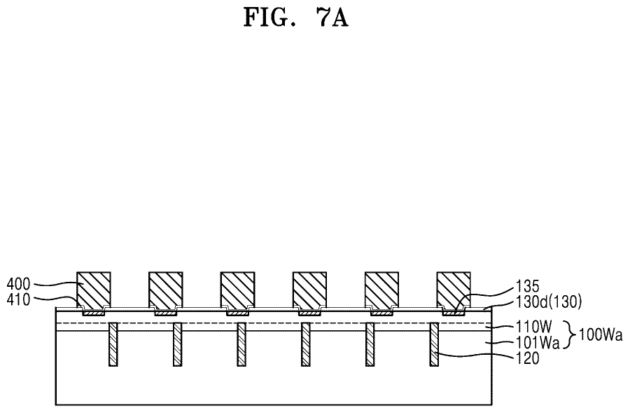

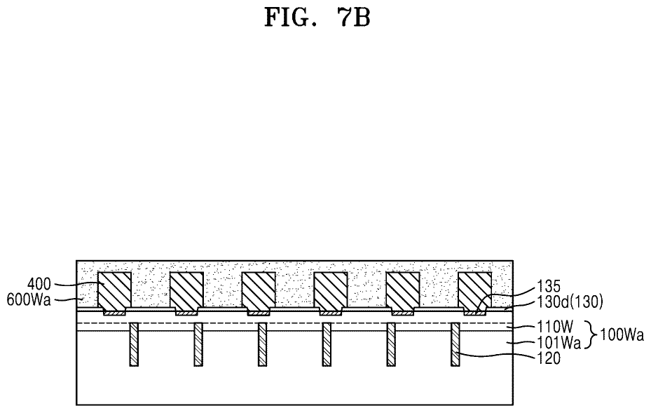

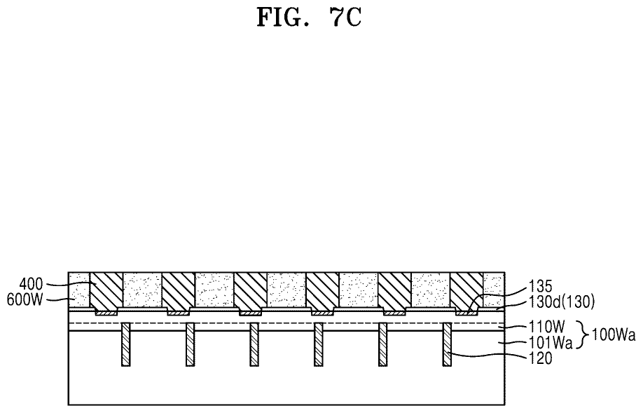

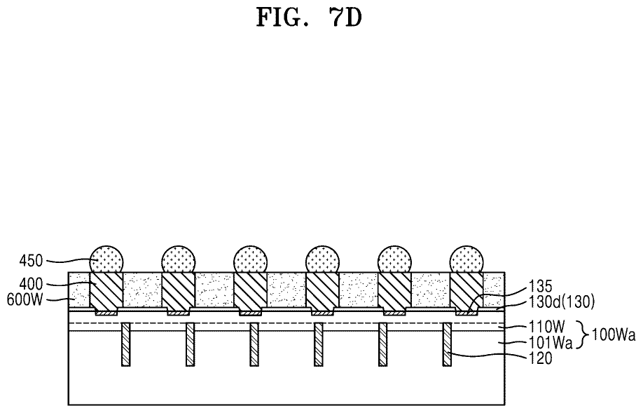

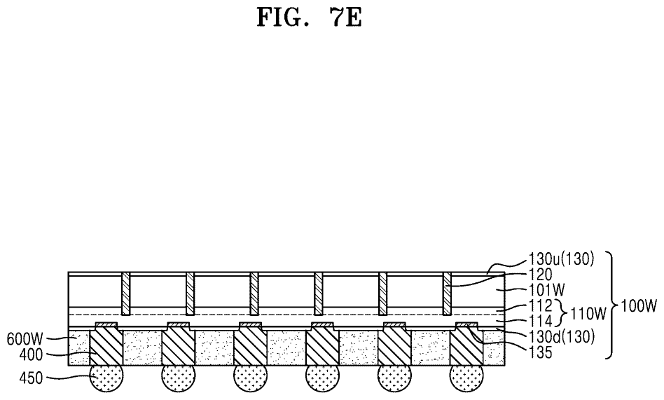

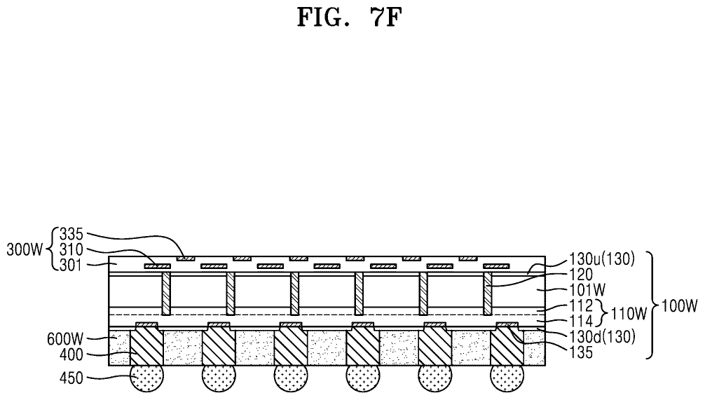

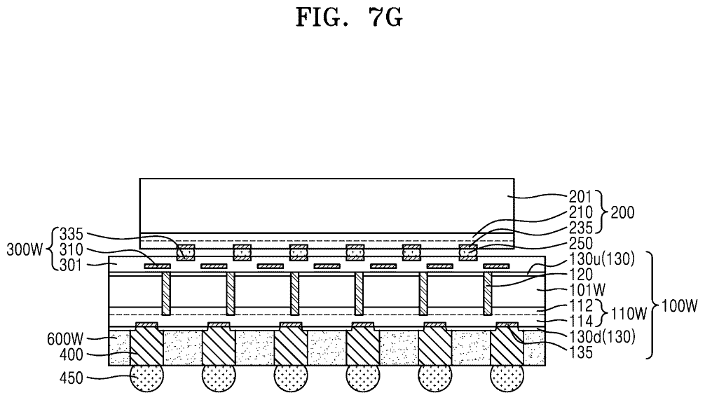

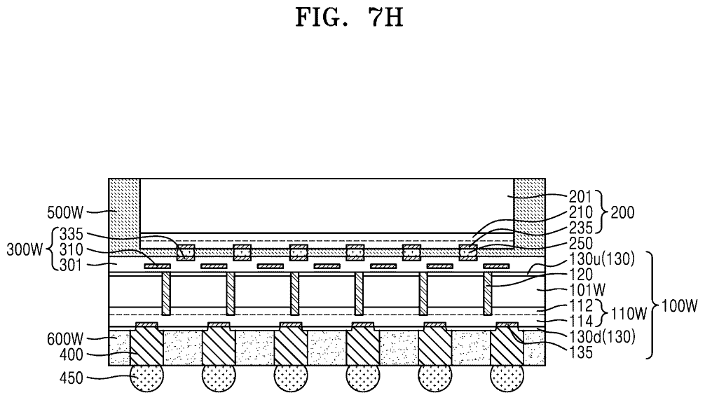

The metal post 400 may be arranged under the first semiconductor chip 100. More particularly, the metal post 400 may be arranged on the chip pad 135 of the first semiconductor chip 100. Although not illustrated, a seed metal layer 410 (see FIG. 7A) may be arranged between the metal post 400 and the chip pad 135, and the metal post 400 may be formed through a plating process, having the seed metal layer 410 as a seed. Forming of the metal post 400 will be more particularly described in the descriptions with reference to FIG. 7A.

The metal post 400 may include a conductive metal and/or alloy, for example, nickel (Ni), copper (Cu), palladium (Pd), platinum (Pt), gold (Au), and/or a combination thereof. However, a material of the metal post 400 is not limited to the aforementioned materials. In the semiconductor package 1000 of the present embodiment, the metal post 400 may include Cu. When the metal post 400 includes Cu, in some embodiments, the metal post 400 may be referred to as a Cu post.

The metal post 400 may have a first height H1 in the vertical direction (the z direction), on a bottom surface of the first semiconductor chip 100. In at least some embodiments, the first height H1 may be substantially identical (or substantially similar) to a thickness of the second encapsulant 600 on the bottom surface of the first semiconductor chip 100. Accordingly, bottom surfaces of the metal post 400 and the second encapsulant 600 may be substantially co-planar to each other (e.g., on the same plane). Here, the first height H1 may be adjusted to a height at which warpage of a first wafer 100W (see FIG. 3B) may be reduced as much as possible when the semiconductor package 1000 of the present embodiment is manufactured at a wafer-level. The first wafer 100W may have the form of a wafer and may include a plurality of first semiconductor chips 100. For example, the first height H1 may be from about 10 micrometers (μm) to about 120μm However, the first height H1 is not limited to the aforementioned numerical range.

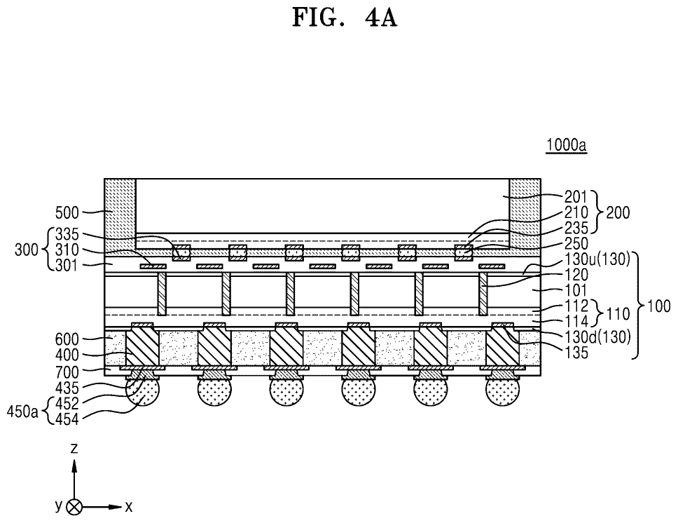

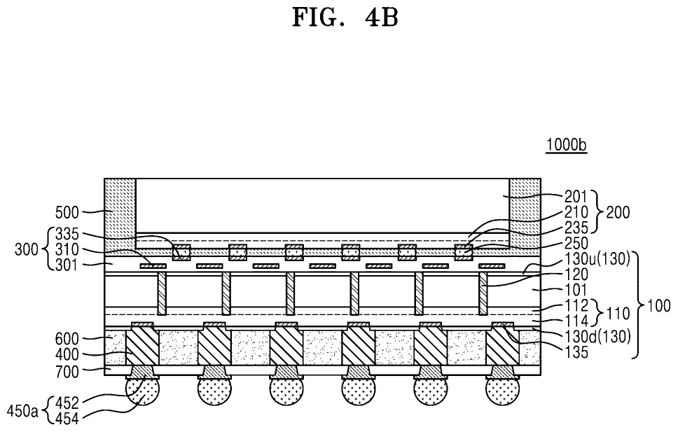

A first connection terminal 450 may be arranged on the metal post 400. Through the first connection terminal 450, the semiconductor package 1000 of the present embodiment may be mounted on a package substrate of an external semiconductor package, a main board, a motherboard, and a system board of an external device, and the like. The first connection terminal 450 may include a solder layer. The solder layer may include, for example, tin (Sn), indium (In), bismuth (Bi), antimony (Sb), Cu, Ag, zinc (Zn), lead (Pb), and/or alloys thereof. For example, the solder layer may include one or more of Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, and/or the like. The first connection terminal 450 is not limited to a solder layer. Other structures of the first connection terminal 450 will be described in more detail in descriptions with reference to FIGS. 4A to 4B.

The first encapsulant 500 may be arranged on the redistribution substrate 300 and encapsulate the second semiconductor chip 200. More particularly, the first encapsulant 500 may cover side surfaces and a bottom surface of the second semiconductor chip 200. In addition, the first encapsulant 500 may fill a space between second connection terminals 250 on the bottom surface of the second semiconductor chip 200. As illustrated in FIG. 1, the first encapsulant 500 may not cover a top surface of the second semiconductor chip 200. Accordingly, the top surface of the second semiconductor chip 200 may be exposed from the first encapsulant 500. However, in some embodiments, the first encapsulant 500 may also cover a portion or the entirety of the top surface of the second semiconductor chip 200.

The first encapsulant 500 may include an insulating material, e.g., a thermosetting resin such as an epoxy resin, a thermoplastic resin such as plastic, a resin further including a reinforcement such as an inorganic filler in addition to the thermosetting resin or the thermoplastic resin, and/or the like. For example, the first encapsulant 500 may include Ajinomoto build-up film (ABF), fire-retardant-4 (FR-4), bismaleimide-triazine (BT) resins, etc. In addition, the first encapsulant 500 may include a molding material such as an epoxy molding compound (EMC) and/or a photosensitive material such as Photo Imageable Encapsulant (PIE). However, a material of the first encapsulant 500 is not limited to the aforementioned materials.

The second encapsulant 600 may be arranged on the bottom surface of the first semiconductor chip 100. More particularly, the second encapsulant 600 may be on the bottom surface of the first semiconductor chip 100 and may cover side surfaces of the metal post 400. As described above, on the bottom surface of the first semiconductor chip 100, a height of the metal post 400 and the thickness of the second encapsulant 600 may be substantially identical (and/or similar) to each other. The first connection terminal 450 arranged on a bottom surface of the metal post 400 may protrude from the bottom surface of the second encapsulant 600. A material of the second encapsulant 600 may have a substantially identical (or similar) Young's modulus compared to the material of the first encapsulant 500 For example, the material of the second encapsulant 600 may be substantially identical (or similar) to the material of the first encapsulant 500. In at least some embodiments, the second encapsulant 600 may include an insulating material, e.g., a thermosetting resin such as an epoxy resin, a thermoplastic resin such as plastic, a resin further including a reinforcement such as an inorganic filler in addition to the thermosetting resin or the thermoplastic resin, and/or the like. However, in some embodiments, the second encapsulant 600 may include a material different from the material of the first encapsulant 500. In addition, by modifying contents of included materials or adjusting time or temperature of thermal processing, physical characteristics such as rigidity or a coefficient of thermal expansion of the second encapsulant 600 may be different from those of the first encapsulant 500.

The semiconductor package 1000 of the present embodiment may be manufactured at the wafer-level. In other words, by performing a series of processes on the first wafer 100W (see FIG. 3B) including the plurality of first semiconductor chips 100, a package structure 1000S (see FIG. 3B) including a plurality of semiconductor packages 1000 may be formed, and the semiconductor package 1000 may be manufactured by performing singulation on the package structure 1000S through a sawing process and/or the like. As mentioned above, as the semiconductor package 1000 is manufactured through the sawing process at the wafer-level, side surfaces of the first semiconductor chip 100, the redistribution substrate 300, the first encapsulant 500, and the second encapsulant 600 may be substantially co-planar (e.g., on the same plane). A method of manufacturing the semiconductor package 1000 will be described in further detail in descriptions with reference to FIGS. 7A to 7H.

The semiconductor package 1000 of the present embodiment, in a structure where two semiconductor chips are stacked, may include the second encapsulant 600 on the bottom surface of the first semiconductor chip 100 to correspond to the first encapsulant 500 encapsulating the second semiconductor chip 200 at an upper portion, and by doing so, warpage may be reduced. More particularly, in the semiconductor package 1000 of the present embodiment, warpage may be significantly reduced at the wafer-level before singulation through the sawing process, and by doing so, a wafer-level test may be easily performed. As a result, the semiconductor package 1000 of the present embodiment may remarkably contribute to improvement in the reliability of the semiconductor package 1000 and an increase in a yield of the semiconductor package 1000. Furthermore, in the semiconductor package 1000 of the present embodiment, the thickness of the second encapsulant 600 may be adjusted by adjusting the height of the metal post 400, and by doing so, warpage may be appropriately controlled considering the total thickness of the semiconductor package 1000.

Hereinafter, an effect of warpage reduction achieved as the semiconductor package 1000 of the present embodiment includes the second encapsulant 600 will be described in further detail with reference to FIGS. 2A to 3B.

In a semiconductor package not including the second encapsulant 600 (like the semiconductor package COM in the comparative example illustrated in FIG. 2A), as seen from an arrow mark, contraction stress may be applied to a first semiconductor chip 1st CH, and expansion stress or tensile stress may be applied to an encapsulant EMC. Accordingly, as marked with a broken line, a neutral axis Nax1, on which stress is zero, may be formed near the first semiconductor chip 1st CH in the z direction.

On the other hand, in a semiconductor package including the second encapsulant 600 like the semiconductor package 1000 of the present embodiment, in FIGS. 2A and 2B, as seen from an arrow mark, expansion stress or tensile stress may be additionally generated due to the second encapsulant 600. Accordingly, as marked with a broken line, a natural axis Nax2, on which stress is zero, may be formed at a lower portion away from the first semiconductor chip 100 in the z direction.

As a result, as seen from FIGS. 3A and 3B, first warpage W1 may occur in a package structure COMS in comparative examples at the wafer-level, and second warpage W2 may occur in the package structure 1000S of the present embodiment at the wafer-level. Here, the package structure COMS may include a plurality of the semiconductor packages COM in the comparative example, and the package structure 1000S may include a plurality of semiconductor packages 1000 of the present embodiment.

The second warpage W2 may be less than the first warpage W1. For example, the second warpage W2 may be ½ of the first warpage W1 or less. However, a relationship between sizes of the first warpage W1 and the second warpage W2 is not limited to the aforementioned numerical range. More particularly, the size of the first warpage W1 may be 1000 micrometers (μm) or greater, and accordingly, the size of the package structure COMS in the comparative example at the wafer-level may exceed a warpage specification allowed for a test device. However, in the package structure 1000S of the at least one embodiment at the wafer-level, the size of the second warpage W2 may be 700μm or less and may sufficiently fulfill the warpage specifications for the test device. Additionally, since the neutral axis Nax2 of the semiconductor package including the second encapsulant 600 is farther from an interface between the first and second semiconductor chips 1^{st} CH and 2^{nd} CH, compared to the neutral axis NAx1, the semiconductor package including the second encapsulant 600 may be less prone to delamination compared to the comparative example.

For reference, in FIGS. 2A and 3A, a reference numeral ‘S’ may indicate a terminal connection, and a reference numeral ‘1st WF’ may indicate a wafer including a plurality of first semiconductor chips 1st-CH. In addition, in FIG. 3B, a reference numeral ‘100W’ may indicate a wafer including a plurality of first semiconductor chips 100.

FIGS. 4A and 4B are cross-sectional views of semiconductor packages 1000a and 1000b according to some embodiments. Descriptions given above in descriptions with reference to FIG. 1 to DB will be briefly given or omitted.

Referring to FIG. 4A, the semiconductor package 1000a may be different from the semiconductor package 1000 illustrated in FIG. 1 in that the semiconductor package 1000a further includes a bump pad 435 and a passivation layer 700. In addition, the semiconductor package 1000a may also be different from the semiconductor package 1000 illustrated in FIG. 1 in terms of a structure of a first connection terminal 450a. More particularly, the semiconductor package 1000a of the present embodiment may include the first semiconductor chip 100, the second semiconductor chip 200, the redistribution substrate 300, the metal post 400, the first encapsulant 500, the second encapsulant 600, and the passivation layer 700. The first semiconductor chip 100, the second semiconductor chip 200, the redistribution substrate 300, the metal post 400, the first encapsulant 500, and the second encapsulant 600 are as described in the descriptions of the semiconductor package 1000 with reference to FIG. 1.

The semiconductor package 1000a of the present embodiment may further include the passivation layer 700 on the bottom surface of the second encapsulant 600. The passivation layer 700 may include, for example, PID. However, a material of the passivation layer 700 is not limited to PID and may include another insulator and/or resin. As illustrated in FIG. 4A, the bump pad 435 may be arranged on the bottom surface of the metal post 400, and the first connection terminal 450a may be arranged on the bump pad 435. The bump pad 435 may have a size in a horizontal direction (an x and/or y direction) greater than the size of the metal post 400. Accordingly, the bump pad 435 may be used for enlarging a contact area between the first connection terminal 450a and the metal post 400.

The first connection terminal 450a may have a bilayer structure. For example, the first connection terminal 450a may include a Cu layer 452 and a solder layer 454. When the Cu layer 452 has a pillar shape, the Cu layer 452 may be referred to as a Cu pillar. However, a structure of the first connection terminal 450a is not limited to the bilayer structure. For example, the first connection terminal 450a may have a CNS structure, a CNCS structure, and the like. Here, C may indicate Cu, N may indicate Ni, and S may indicate solder. Accordingly, the aforementioned bilayer structure of the first connection terminal 450a including the Cu layer 452 and the solder layer 454 may correspond to the CS structure. In some embodiments, the first connection terminal 450a may only include the Cu layer, without including the solder layer. Furthermore, in some embodiments, the first connection terminal 450a may have a C4 structure. The C4 structure may include a thin Cu layer having a saucer shape and a solder layer on the Cu layer.

Referring to FIG. 4B, the semiconductor package 1000b may be different from the semiconductor package 1000a illustrated in FIG. 4A in that the bump pad 435 is omitted from the semiconductor package 1000b. As the bump pad 435 is omitted, the first connection terminal 450a may be directly combined to the bottom surface of the metal post 400. The passivation layer 700 and the first connection terminal 450a are as described in the descriptions of the semiconductor package 1000a illustrated in FIG. 4A.

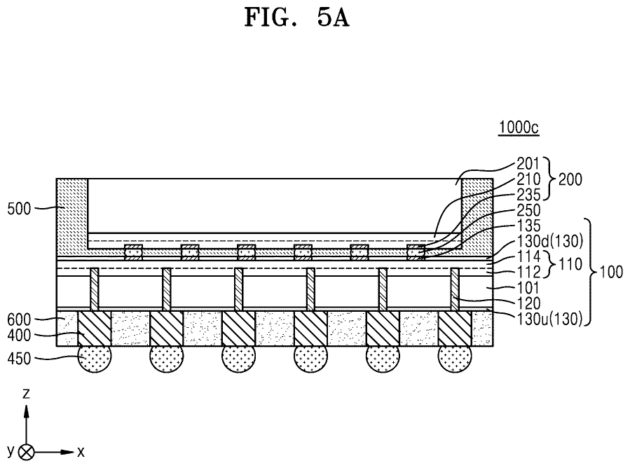

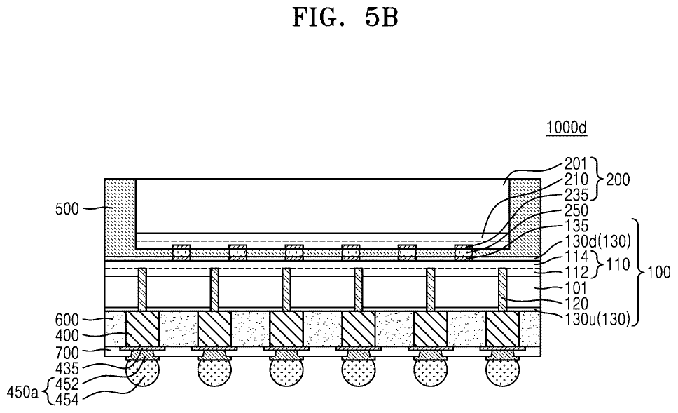

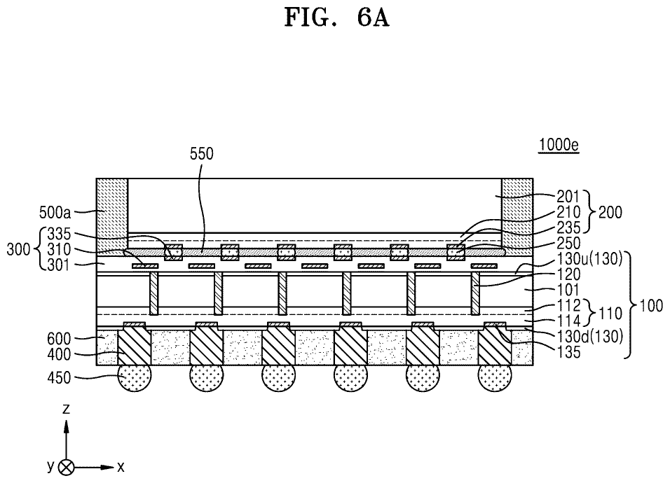

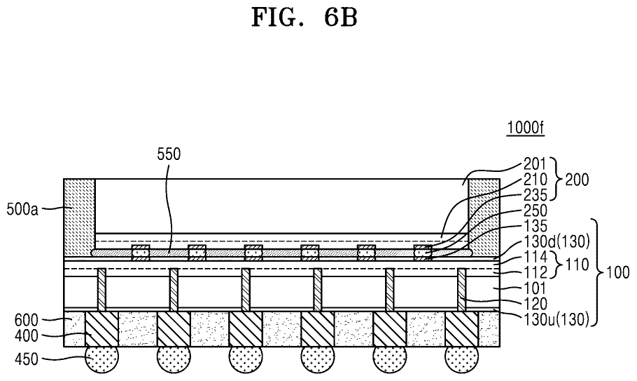

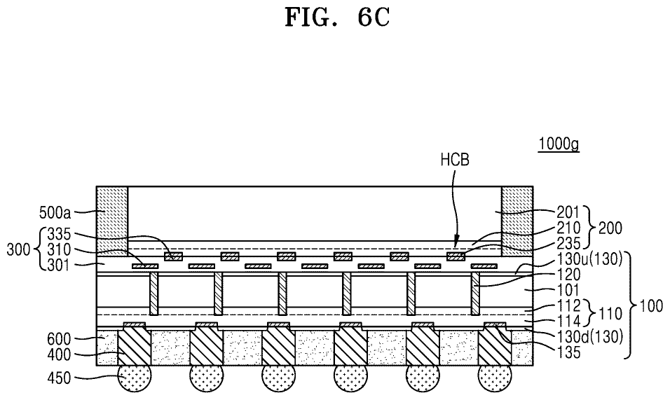

FIGS. 5A and 5B are cross-sectional views of semiconductor packages 1000c and 1000d according to embodiments. Descriptions given above with reference to FIGS. 1 to 4B will be briefly given or omitted.

Referring to FIG. 5A, the semiconductor package 1000c may be different from the semiconductor package 1000 illustrated in FIG. 1 in that the first semiconductor chip 100 is inversely arranged and the redistribution substrate 300 is omitted. More particularly, the semiconductor package 1000c of the present embodiment may include the first semiconductor chip 100, the second semiconductor chip 200, the metal post 400, the first encapsulant 500, and the second encapsulant 600. The second semiconductor chip 200, the metal post 400, the first encapsulant 500, and the second encapsulant 600 are as described in the descriptions of the semiconductor package 1000 illustrated in FIG. 1.

In the semiconductor package 1000c of the present embodiment, compared with the first semiconductor chip 100 of the semiconductor package 1000 illustrated in FIG. 1, the first semiconductor chip 100 may be arranged in an upside-down structure. For example, in the z direction, the substrate 101 may be at a lower portion, and the active layer 110 may be at an upper portion. Accordingly, a top surface of the first semiconductor chip 100 may correspond to a front-side (e.g., an active surface), and a bottom surface of the first semiconductor chip 100 may correspond to a back-side (e.g., an inactive surface).

In the semiconductor package 1000c of the present embodiment, the second semiconductor chip 200 may be directly mounted on the first semiconductor chip 100 without mediation of the redistribution substrate 300. That is, the second semiconductor chip 200 may be directly mounted on the first semiconductor chip 100 through the second connection terminal 250. The second connection terminal 250 may connect the chip pad 135 of the first semiconductor chip 100 and the chip pad 235 of the second semiconductor chip 200 to each other. A bottom surface of the second semiconductor chip 200 may correspond to a front-side (e.g., an active surface). Accordingly, the front-side of the second semiconductor chip 200 faces the front side of the first semiconductor chip 100, and such a stack structure is referred to as a front-to-front (F2F) stack structure. In the semiconductor packages 1000, 1000a, and 1000b respectively illustrated in FIGS. 1, 4A, and 4B, when the redistribution substrate 300 is not considered, the front-side of the second semiconductor chip 200 faces the back-side of the first semiconductor chip 100, and such a stack structure is referred to as a front-to-back (F2B) stack structure.

The metal post 400 and the second encapsulant 600 may be arranged on the bottom surface of the first semiconductor chip 100 (e.g., the back-side that is the inactive surface). The metal post 400 may be directly connected to the through electrode 120 of the first semiconductor chip 100. Although not illustrated, an upper pad may be arranged between the metal post 400 and the through electrode 120. In some embodiments, a redistribution substrate may be arranged between the first semiconductor chip 100 and the metal post 400. When the redistribution substrate is arranged, the through electrode 120 may be connected to the metal post 400 through redistribution lines of the redistribution substrate.

Referring to FIG. 5B, the semiconductor package 1000d of the present embodiment may be different from the semiconductor package 1000c illustrated in FIG. 5A in that the semiconductor package 1000d further includes the passivation layer 700 and the first connection terminal 450a has a bilayer structure. The passivation layer 700 and the bilayer structure of the first connection terminal 450a are as described in the descriptions of the semiconductor package 1000a illustrated in FIG. 4A. As illustrated in FIG. 5B, the bump pad 435 may be arranged on the bottom surface of the metal post 400, and the first connection terminal 450a may be arranged on the bump pad 435. However, like in the semiconductor package 1000b illustrated in FIG. 4B, the bump pad 435 may be omitted. In addition, the first connection terminal 450a is not limited to the CS structure and may have various structures, e.g., a CNS structure, a CNCS structure, a C4 structure, a Cu layer structure, and/or the like.

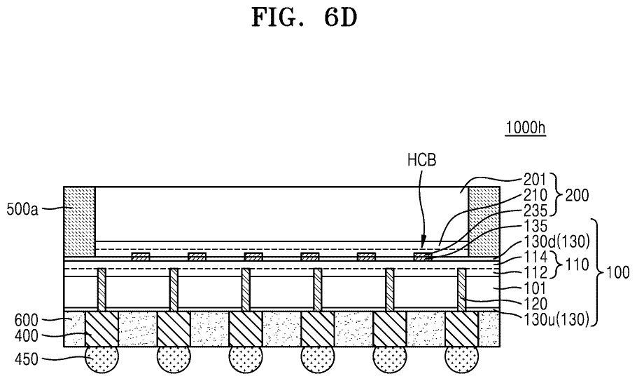

FIGS. 6A to 6D are cross-sectional views of semiconductor packages 1000e and 1000f according to embodiments. Descriptions given above with reference to FIGS. 1 to 5B will be briefly given or omitted.

Referring to FIG. 6A, the semiconductor package 1000e may be different from the semiconductor package 1000 illustrated in FIG. 1 in that an adhesive layer 550 is arranged between the second semiconductor chip 200 and the redistribution substrate 300. More particularly, the semiconductor package 1000e may include the first semiconductor chip 100, the second semiconductor chip 200, the redistribution substrate 300, the metal post 400, a first encapsulant 500a, and the second encapsulant 600. The first semiconductor chip 100, the second semiconductor chip 200, the redistribution substrate 300, the metal post 400, and the second encapsulant 600 are as described in the descriptions of the semiconductor package 1000 illustrated in FIG. 1.

The first encapsulant 500a may cover side surfaces of the second semiconductor chip 200 and side surfaces of the adhesive layer 550. Unlike the semiconductor package 1000 illustrated in FIG. 1, a space between the second semiconductor chip 200 and the redistribution substrate 300 and a space between second connection terminals 250 on the bottom surface of the second semiconductor chip 200 may each be filled with the adhesive layer 550. The adhesive layer 550 may include a non-conductive film (NCF). Accordingly, the second semiconductor chip 200 may be mounted on the redistribution substrate 300 through a thermal compression (TC)-NCF process.

For reference, in the semiconductor package 1000 illustrated in FIG. 1, the space between the second semiconductor chip 200 and the redistribution substrate 300 may be filled with the first encapsulant 500 through a molded under-fill (MUF) process or a mass-reflow (MR)-MUF process. General underfills or adhesives may be arranged between the second semiconductor chip 200 and the redistribution substrate 300 through a capillary-underfill process or a TC-Non-Conductive Paste (NCP) process.

Referring to FIG. 6B, the semiconductor package 1000f may be different from the semiconductor package 1000c illustrated in FIG. 5A in that the adhesive layer 550 is arranged between the first semiconductor chip 100 and the second semiconductor chip 200. More particularly, the semiconductor package 1000f of the present embodiment may include the first semiconductor chip 100, the second semiconductor chip 200, the metal post 400, the first encapsulant 500a, and the second encapsulant 600. The first semiconductor chip 100, the second semiconductor chip 200, the metal post 400, and the second encapsulant 600 are as described in the descriptions of the semiconductor package 1000c illustrated in FIG. 5A.

The first encapsulant 500a may cover the side surfaces of the second semiconductor chip 200 and the side surfaces of the adhesive layer 550 on the first semiconductor chip 100. Unlike the semiconductor package 1000c illustrated in FIG. 5A, a space between the first semiconductor chip 100 and the second semiconductor chip 200 and the space between the second connection terminals 250 on the bottom surface of the second semiconductor chip 200 may each be filled with the adhesive layer 550. The adhesive layer 550 may include an NCF. Accordingly, the second semiconductor chip 200 may be mounted on the first semiconductor chip 100 through the TC-NCF process. However, the adhesive layer 550 is not limited to an NCF, and may also include general underfills or adhesives.

Referring to FIG. 6C, a semiconductor package 1000g may be different from the semiconductor package 1000 illustrated in FIG. 1 in that the second semiconductor chip 200 is mounted on the redistribution substrate 300 through hybrid Cu bonding (HCB). More particularly, the semiconductor package 1000g may include the first semiconductor chip 100, the second semiconductor chip 200, the redistribution substrate 300, the metal post 400, the first encapsulant 500a, and the second encapsulant 600. The first semiconductor chip 100, the redistribution substrate 300, the metal post 400, and the second encapsulant 600 are as described in the descriptions of the semiconductor package 1000 illustrated in FIG. 1.

The second semiconductor chip 200 may be mounted on the redistribution substrate 300 through hybrid cupper bonding (HCB). Here, HCB may indicate a bonding method obtained by combination of pad-to-pad bonding and insulator-to-insulator bonding. As pads are usually formed of Cu, pad-to-pad bonding is also referred to as Cu-to-Cu bonding. In the semiconductor package 1000g of the present embodiment, through the HCB, the substrate pad 335 of the redistribution substrate 300 and the chip pad 235 of the second semiconductor chip 200 may be combined with each other, and an insulating layer of the redistribution substrate 300 and an insulating layer of the second semiconductor chip 200 may be combined with each other. In some embodiment, HCB may be simply referred to as HB.

As the second semiconductor chip 200 is mounted on the redistribution substrate 300 through HCB, the first encapsulant 500a may cover the side surfaces of the second semiconductor chip 200 on the redistribution substrate 300.

Referring to FIG. 6D, a semiconductor package 1000h may be different from the semiconductor package 1000c illustrated in FIG. 5A in that the second semiconductor chip 200 is mounted on the first semiconductor chip 100 through HCB. More particularly, the semiconductor package 1000h may include the first semiconductor chip 100, the second semiconductor chip 200, the metal post 400, the first encapsulant 500a, and the second encapsulant 600. The first semiconductor chip 100, the metal post 400, and the second encapsulant 600 are as described in the descriptions of the semiconductor package 1000c illustrated in FIG. 5A.

The second semiconductor chip 200 may be mounted on the first semiconductor chip 100 through HCB. Accordingly, in the semiconductor package 1000h of the present embodiment, through HCB, the chip pad 135 of the first semiconductor chip 100 and the chip pad 235 of the second semiconductor chip 200 may be combined with each other, and an insulating layer of the first semiconductor chip 100 and the insulating layer of the second semiconductor chip 200 may be combined with each other.

As the second semiconductor chip 200 is mounted on the first semiconductor chip 100 through HCB, the first encapsulant 500a may cover the side surfaces of the second semiconductor chip 200 on the first semiconductor chip 100.

Although the semiconductor packages 1000, and 1000a to 1000h) having a package structure in which two semiconductor chips are stacked have been described, the inventive concepts are not limited thereto. For example, in a package structure in which two or semiconductor chips are stacked, the inventive concepts may have impacts semiconductor packages having any structure including encapsulants at upper portions and lower portions. For reference, semiconductor packages may be approximately sorted into a three-dimensional (3D) package structure in which semiconductor chips are stacked only in a vertical direction and a 2.x-D (e.g., a 2.5-D) package in which semiconductor chips are complexly stacked in a horizontal direction and the vertical direction. The 3D package structure may also be referred to as a vertical integration (VI) package structure.

FIGS. 7A through 7H are cross-sectional views schematically illustrating a method of fabricating a semiconductor package, according to at least one embodiment. FIGS. 7A through 7H will be described with reference to FIG. 1, and descriptions given above with reference to FIGS. 1 to 6D will be briefly given or emitted.

Referring to FIG. 7A, first, the metal post 400 is formed on an initial first wafer 100Wa. The initial first wafer 100Wa may include a plurality of initial first semiconductor chips. Accordingly, the initial first wafer 100Wa may include an initial wafer 101Wa, an active layer 110W and the through electrode 120. Here, the initial first wafer 100Wa, which is in a state where a back-grinding process has not been performed, may have a thickness greater than a thickness of the first wafer 100W after the back-grinding process, and in the initial first wafer 100Wa, a bottom surface of the through electrode 120 may not be exposed. For reference, when the metal post 400 is formed on the initial first wafer 100Wa, the initial first wafer 100Wa may be fixed onto a first carrier substrate through the adhesive layer.

The metal post 400 may be arranged on the chip pad 135 and formed through a plating process. The plating process may be performed by using the seed metal layer 410 on the chip pad 135. The seed metal layer 410 may include various metal materials, e.g., Cu, Ti, Ta, TiN, TaN, and/or the like. However, a material of the seed metal layer 410 is not limited to the aforementioned materials.

To describe a process of forming the metal post 400 in further detail, the seed metal layer 410 and a photoresist (PR) layer are formed on the initial first wafer 100Wa. Next, a PR pattern is formed by performing a photo process on the PR layer. Here, the photo process may include an exposure process, a development process, a washing process, and/or the like. The PR pattern may include a plurality of through holes, and on a bottom surface of a through hole, the seed metal layer 410 of a portion corresponding to the chip pad 135 may be exposed. Next, the plating process is performed by using the seed metal layer 410 to form the metal posts 400 in the through holes. The metal post 400 may include, for example, Cu. Subsequently, the PR pattern is removed through an ashing/strip process. In addition, the seed metal layer 410 exposed between the metal posts 400 by removing the PR pattern is removed through an etching process. In the etching process, the seed metal layer 410 under the metal post 400 may be maintained. In the following embodiments, for convenience, only a portion corresponding to the semiconductor package 1000 of FIG. 1 will be illustrated, and the seed metal layer 410 will not be illustrated.

Referring to FIG. 7B, after the metal post 400 is formed, an initial second encapsulant 600Wa covering the metal post 400 is formed on the initial first wafer 100Wa. The initial second encapsulant 600Wa may cover the side surfaces and a top surface of the metal post 400. In addition, the initial second encapsulant 600Wa may have a size corresponding to a size of the initial first wafer 100Wa. That is, the initial second encapsulant 600Wa may have a wafer-level size. A material of the initial second encapsulant 600Wa is as described with reference to the first encapsulant 500 and the second encapsulant 600 of the semiconductor package 1000 illustrated in FIG. 1.

Referring to FIG. 7C, after forming the initial second encapsulant 600Wa, a second encapsulant 600W is formed by removing a top portion of the initial second encapsulant 600Wa, e.g., through a grinding process. Through the grinding process, the top surface of the metal post 400 may be exposed from the second encapsulant 600W. In addition, the top surface of the metal post 400 and a top surface of the second encapsulant 600W may be substantially a same plane. Here, the top surfaces of the metal post 400 and the second encapsulant 600W may correspond to the bottom surfaces of the metal post 400 and the second encapsulant 600W of the semiconductor package 1000 illustrated in FIG. 1.

Referring to FIG. 7D, after forming the second encapsulant 600W, the first connection terminal 450 is formed on the metal post 400. The first connection terminal 450 is as described about the first connection terminal 450 of the semiconductor package 1000 illustrated in FIG. 1.

Referring to FIG. 7E, after forming the first connection terminal 450, the first wafer 100W is formed by removing a back side portion of the initial first wafer 100Wa through a back-grinding process. After the back-grinding process, the upper protective layer 130u may be formed on the back side of the first wafer 100W. The top surface of the through electrode 120 may be exposed from the upper protective layer 130u. Although not shown, an upper pad may be formed on the top surface of the through electrode 120. The through electrode 120 or the upper pad may penetrate the upper protective layer 130u. The back-grinding may be performed after separating the initial first wafer 100Wa from the first carrier substrate and combining a surface of the initial first wafer 100Wa, in which the first connection terminals are formed, to a second carrier substrate through the adhesive layer.

Referring to FIG. 7F, after forming the first wafer 100W, a redistribution substrate 300W is formed on the back side of the first wafer 100W. The redistribution substrate 300W may also have a size corresponding to the size of the first wafer 100W. That is, the redistribution substrate 300W may have a size at the wafer-level. Except the size, the redistribution substrate 300W is as described with about the redistribution substrate 300 of the semiconductor package 1000 illustrated in FIG. 1.

Referring to FIG. 7G, after forming the redistribution substrate 300W, the second semiconductor chip 200 is mounted on the redistribution substrate 300W. The second semiconductor chip 200 may be arranged at a position corresponding to a position of the first semiconductor chip 100 of the first wafer 100W. Accordingly, a plurality of second semiconductor chips 200 may be mounted on the redistribution substrate 300W, to correspond to the plurality of first semiconductor chips 100 of the first wafer 100W. The second semiconductor chip 200 may be mounted on the redistribution substrate 300W through the second connection terminal 250. That is, the second connection terminal 250 may connect the chip pad 235 of the second semiconductor chip 200 and the substrate pad 335 of the redistribution substrate 300W to each other.

Referring to FIG. 7H, after the second semiconductor chip 200 is mounted, a first encapsulant 500W encapsulating the second semiconductor chip 200 is formed on the redistribution substrate 300W. The first encapsulant 500W may have a size corresponding to the size of the first wafer 100W or the redistribution substrate 300W. That is, the first encapsulant 500W may have a wafer-level size. Except the size, the first encapsulant 500W is as described about the first encapsulant 500 of the semiconductor package 1000 illustrated in FIG. 1.

Next, the first wafer 100W and a structure on the first wafer 100W, e.g., a package structure 1000S (see FIG. 3B) including the plurality of semiconductor packages 1000, may be separated from the second carrier substrate and the package structure 1000S may be singulated in a ring mount apparatus through the sawing process, and by doing so, the semiconductor package 1000 illustrated in FIG. 1 may be completely manufactured. For reference, a process from combining the second carrier for the back-grinding process (see FIG. 7) to separating the second carrier after the forming of the first encapsulant 500W (see FIG. 7H) is referred to as a wafer supporting system (WSS) process.

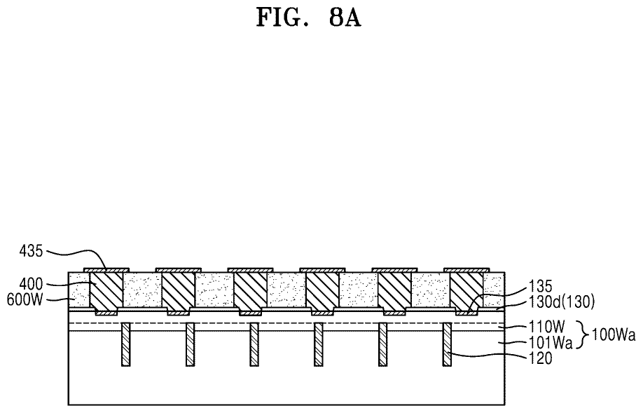

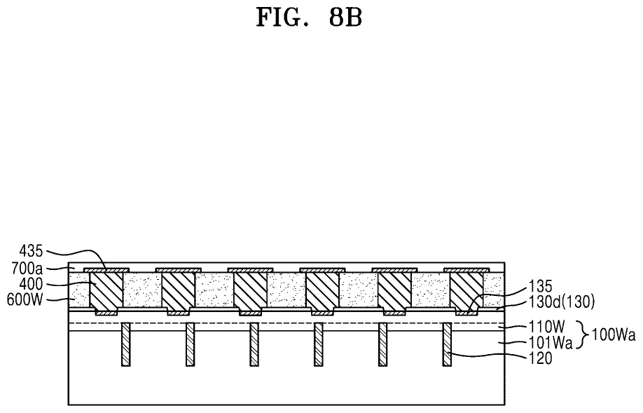

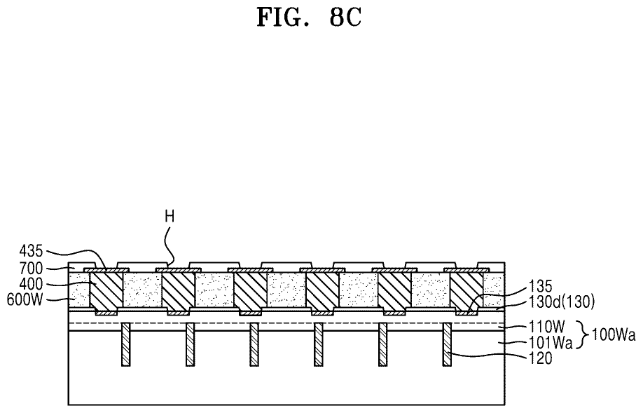

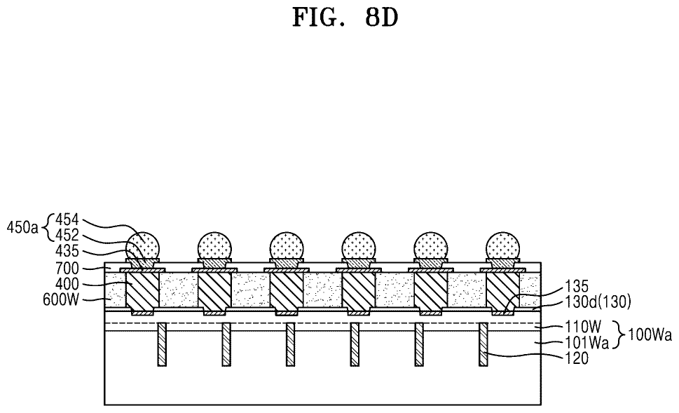

FIGS. 8A to 8D are cross-sectional views schematically illustrating a method of fabricating a semiconductor package, according to at least one embodiment. The method will be described with reference to FIG. 4A, and descriptions given above with reference to FIGS. 7A to 7H will be briefly given or omitted.

Referring to FIG. 8A, the metal post 400 and the second encapsulant 600W are formed on the initial first wafer 100Wa through the process shown in FIGS. 7A to 7C. Next, the bump pad 435 is formed on the top surface of the metal post 400. The bump pad 435 may include, for example, Cu. In addition, the bump pad 435 may be formed through a plating process.

Referring to FIG. 8B, after the forming of the bump pad 435, a first material layer 700a covering the bump pad 435 is formed on the metal post 400 and the second encapsulant 600W. The first material layer 700a may include a material available for a photo process. For example, the first material layer 700a may include a PID. However, a material of the first material layer 700a is not limited to PID.

Referring to FIG. 8C, after the forming of the first material layer 700a, a through hole H is formed in the first material layer 700a through a photo process. The through hole H may expose at least a portion of a top surface of the bump pad 435. By forming the through hole H, the passivation layer 700 based on the first material layer 700a may be formed.

Referring to FIG. 8D, after the forming of the passivation layer 700, the first connection terminal 450a is formed on the bump pad 435. The first connection terminal 450a may include the Cu layer 452 and the solder layer 454. The first connection terminal 450a is as described about the first connection terminal 450a of the semiconductor package 1000a illustrated in FIG. 4A. In addition, in the process shown in FIG. 8D, the first connection terminal may be formed in various structures, e.g., a CNS structure, a CNCS structure, a C4 structure, or a structure only including Cu, without being limited to the CS structure.

Next, through the processes shown in FIG. 7E to 7H, the semiconductor package 1000a illustrated in FIG. 4A may be completely manufactured.

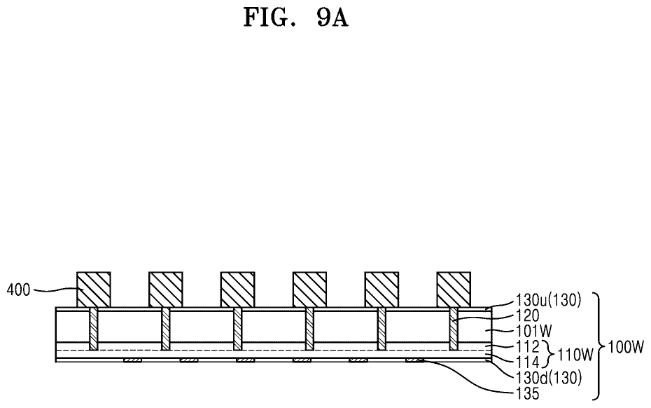

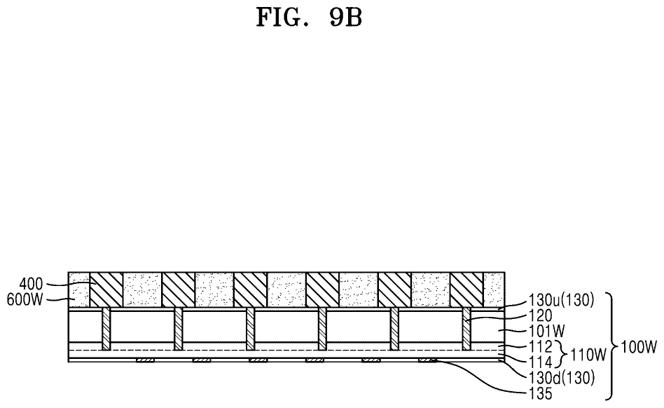

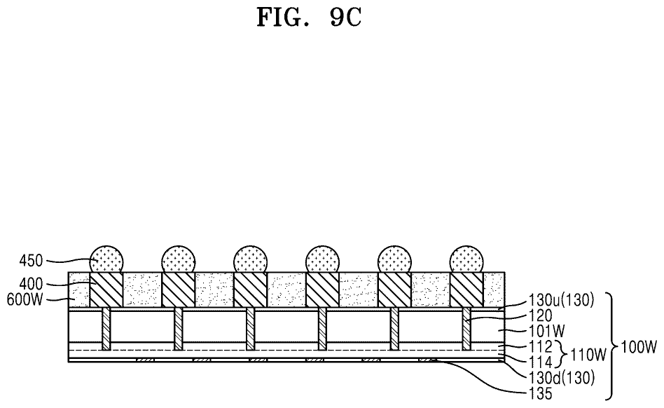

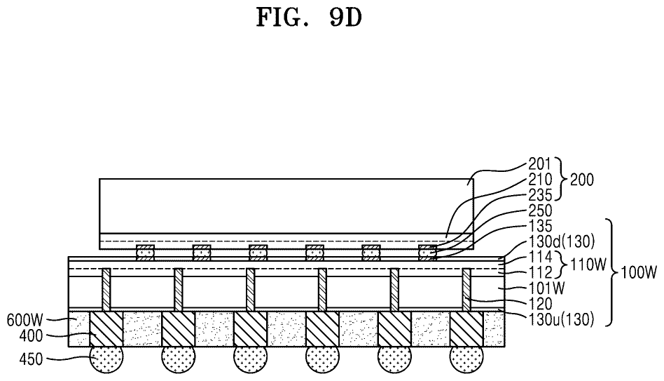

FIGS. 9A to 9D are cross-sectional views schematically illustrating a method of fabricating a semiconductor package, according to at least one embodiment. The method will be described with reference to FIG. 5A, and descriptions given above with reference to FIGS. 7A to 7H will be briefly given or omitted.

Referring to FIG. 9A, first, the first wafer 100W is formed by performing a back-grinding process on the initial first wafer 100Wa. Next, the metal post 400 is formed on the back-side of the first wafer 100W. The method of forming the metal post 400 is the same as the description given above with reference to FIG. 7A. In the back-grinding process and the process of forming the metal post 400, the initial first wafer 100Wa may be fixed onto the first carrier substrate through the adhesive layer.

Referring to FIG. 9B, after the forming of the metal post 400, the second encapsulant 600W is formed on the back side of the first wafer 100W. The second encapsulant 600W may be formed through the processes shown in FIGS. 7B and 7C. Accordingly, the second encapsulant 600W may cover the side surfaces of the metal post 400, and the top surface of the metal post 400 and a top surface of the second encapsulant 600W may be substantially a same plane. In addition, the second encapsulant 600W may have a size corresponding to the size of the first wafer 100W. That is, the second encapsulant 600W may have a wafer-level size.

Referring to FIG. 9C, after the forming of the second encapsulant 600W, the first connection terminal 450 is formed on the metal post 400. The first connection terminal 450 is as described in the description about the first connection terminal 450 of the semiconductor package 1000 illustrated in FIG. 1.

Referring to FIG. 9D, after the forming of the first connection terminal 450, the second semiconductor chip 200 is mounted on the front-side of the first wafer 100W. The second semiconductor chip 200 may be arranged at the position corresponding to the position of the first semiconductor chip 100 of the first wafer 100W. Accordingly, a plurality of second semiconductor chips 200 may be mounted on the first wafer 100W, to correspond to the plurality of first semiconductor chips 100 of the first wafer 100W. The second semiconductor chip 200 may be mounted on the first wafer 100W through the second connection terminal 250. That is, the second connection terminal 250 may connect the chip pad 235 of the second semiconductor chip 200 and the chip pad 135 of the first wafer 100W to each other.

The mounting of the second semiconductor chip 200 may be performed after separating the first wafer 100W from the first carrier substrate and combine a surface of the first wafer 100W, on which the first connection terminals 450 are formed, to the second carrier substrate through the adhesive layer.

After the mounting of the second semiconductor chip 200, the first encapsulant 500W is formed through the process shown in FIG. 7H. The first encapsulant 500W may have a size corresponding to the size of the first wafer 100W or the redistribution substrate 300W. That is, the first encapsulant 500W may have the wafer-level size.

Next, a package structure including a plurality of semiconductor packages 1000c may be separated from the second carrier substrate, and the package structure may be singulated through a sawing process in the ring mount apparatus, and by doing so, the semiconductor package 1000c illustrated in FIG. 5A may be completely manufactured.

Although the inventive concepts have been described with reference to the accompanying drawings, the description is only used to provide examples, and it would be understood to those skilled in the art that various modifications and other equivalent embodiments may be made therefrom. Accordingly, the scope of the inventive concepts will be determined according to the following claims.

While the inventive concepts have been particularly shown and described with reference to embodiments thereof, it will be understood that various changes in form and details may be made therein without departing from the spirit and scope of the following claims.

What is claimed is:

1. A semiconductor package comprising:
a first semiconductor chip;
a redistribution substrate on a top surface of the first semiconductor chip;
a second semiconductor chip on a top surface of the redistribution substrate such that the redistribution substrate connects the second semiconductor chip to the first semiconductor chip;
a first encapsulant on the redistribution substrate and encapsulating the second semiconductor chip;
a metal post on a bottom surface of the first semiconductor chip; and
a second encapsulant on the bottom surface of the first semiconductor chip and covering side surfaces of the metal post.

2. The semiconductor package of claim 1, wherein
the first semiconductor chip comprises a first substrate and a first active layer under the first substrate, and
the metal post is on a bottom surface of the first active layer.

3. The semiconductor package of claim 2, wherein
the first semiconductor chip further comprises a through electrode penetrating the first substrate, and
the first active layer is connected to the redistribution substrate through the through electrode.

4. The semiconductor package of claim 1, wherein
the second semiconductor chip comprises a second substrate and a second active layer under the second substrate, and
the second semiconductor chip is mounted on the redistribution substrate through a second connection terminal on a bottom surface of the second active layer.

5. The semiconductor package of claim 1, wherein a bottom surface of the metal post and a bottom surface of the second encapsulant are substantially co-planar.

6. The semiconductor package of claim 1, further comprising:
a first connection terminal on a bottom surface of the metal post.

7. The semiconductor package of claim 1, further comprising:
a first connection terminal on a bottom surface of the metal post, and
a passivation layer on a bottom surface of the second encapsulant and covering at least a portion of side surfaces of the first connection terminal.

8. The semiconductor package of claim 7, further comprising:
a bump pad between the metal post and the first connection terminal.

9. The semiconductor package of claim 1, wherein each of the first encapsulant and the second encapsulant comprise an epoxy molding compound (EMC).

10. The semiconductor package of claim 1, wherein, in a cross-sectional view,
an area of the first semiconductor chip is greater than an area of the second semiconductor chip, and
side surfaces of the first semiconductor chip, the redistribution substrate, the first encapsulant, and the second encapsulant are substantially co-planar.

11. The semiconductor package of claim 1, wherein
one of the first semiconductor chip and the second semiconductor chip comprises a logic chip, and
another one of the first semiconductor chip and the second semiconductor chip comprises at least one of a logic chip or a memory chip.

12. A semiconductor package comprising:
a first semiconductor chip;
a second semiconductor chip over the first semiconductor chip;
a first encapsulant over the first semiconductor chip and encapsulating the second semiconductor chip;
a metal post on a bottom surface of the first semiconductor chip;
a second encapsulant on the bottom surface of the first semiconductor chip and covering side surfaces of the metal post; and
a first connection terminal on a bottom surface of the metal post,
wherein a top surface of the first semiconductor chip comprises an active surface and a bottom surface of the second semiconductor chip comprises an active surface.

13. The semiconductor package of claim 12, wherein
the first semiconductor chip comprises a first substrate, a first active layer over the first substrate, and a through electrode penetrating the first substrate,
the first active layer includes the active surface of the first semiconductor chip, and
the first active layer is connected to the metal post through the through electrode.

14. The semiconductor package of claim 13, wherein
the second semiconductor chip comprises a second substrate and a second active layer under the second substrate, the second active layer including the active surface of the second semiconductor chip, and
the second semiconductor chip is mounted on the first semiconductor chip through a second connection terminal on a bottom surface of the second active layer.

15. The semiconductor package of claim 12, further comprising:
a passivation layer covering a bottom surface of the second encapsulant,
wherein the first connection terminal comprises a lower layer penetrating the passivation layer and an upper layer on the lower layer.

16. A semiconductor package comprising:
a first semiconductor chip;
a second semiconductor chip over the first semiconductor chip;
a first encapsulant over the first semiconductor chip and encapsulating the second semiconductor chip;
a metal post on a bottom surface of the first semiconductor chip; and
a second encapsulant on the bottom surface of the first semiconductor chip and covering side surfaces of the metal post.

17. The semiconductor package of claim 16, further comprising:
a redistribution substrate over the first semiconductor chip,
wherein the second semiconductor chip is mounted on the redistribution substrate,
the first encapsulant surrounds the second semiconductor chip on the redistribution substrate,
the first semiconductor chip comprises an active surface as the bottom surface, and
the second semiconductor chip comprises an active surface as a bottom surface.

18. The semiconductor package of claim 17, wherein
the first semiconductor chip comprises a first substrate, a first active layer under the first substrate, and a through electrode penetrating the first substrate,
the first active layer includes the active layer of the first semiconductor chip, and
the first active layer is connected to the redistribution substrate through the through electrode.

19. The semiconductor package of claim 16, wherein
a top surface of the first semiconductor chip comprises an active surface and a bottom surface of the second semiconductor chip comprises an active surface,
the first semiconductor chip comprises a first substrate, a first active layer over the first substrate, and a through electrode penetrating the first substrate,
the first active layer includes the active surface of the first semiconductor chip, and
the first active layer is connected to the metal post through the through electrode.

20. The semiconductor package of claim 16, further comprising at least one of:
a connection terminal on a bottom surface of the metal post; or
a passivation layer covering a bottom surface of the second encapsulant, and a first connection terminal penetrating the passivation layer such that the first connection terminal is connected to the metal post.
